(19) United States
(12) Patent Application Publication
(10) Pub. No.: US 2016/0372317 A1
(43) Pub. Date: Dec. 22, 2016

(54) DEVICE AND METHOD FOR CLEANING BACKSIDE OR EDGE OF WAFER

(71) Applicant: IMT CO., LTD, Hwaseibg-si (KR)

(72) Inventors: Jong Myoung LEE, Anyang-city (KR); Kyu-pil LEE, Hwaseong-si (KR); Han-seop CHOE, Bucheon-si (KR)

(21) Appl. No.: 15/122,229

(22) PCT Filed: Aug. 25, 2014
(86) PCT No.: PCT/KR2014/007859

§ 371 Date: Aug. 29, 2016

(30) Foreign Application Priority Data
Mar. 6, 2014 (KR) 10-2014-0026371
May 19, 2014 (KR) 10-2014-0059644

(51) Int. Cl. H01L 21/02; H01L 21/428; B08B 1/00; B08B 15/04; B08B 3/02; B08B 3/12; H01L 21/67; B08B 7/00

(52) U.S. Cl. CPC H01L 21/0209; H01L 21/02087; H01L 21/67051; H01L 21/428; B08B 7/0042; B08B 15/04; B08B 3/02; B08B 3/12; B08B 1/002

(57) ABSTRACT

A wafer back surface cleaning apparatus for removing foreign substance on a back surface of a wafer with a pulse-wave laser beam is disclosed. The wafer back surface cleaning apparatus comprises a rotating unit for rotating the wafer in condition that the outer portion of the back surface of the wafer is exposed; and a laser beam irradiating unit for irradiating a pulse-wave laser beam onto the outer portion of the back surface of the wafer, wherein the pulse-wave laser beam irradiated location on the wafer changes depending on the rotation of the wafer.

### TECHNICAL FIELD

The present invention relates to an apparatus and a method for removing fine foreign substances adhered to a back surface and/or an edge of a wafer with a laser beam. More specifically, the present invention relates to the apparatus and the method able to clean locally only the back surface or the edge of the wafer more quickly, with less damage to the wafer and with less re-contamination to the wafer during cleaning process.

### BACKGROUND ART

FIG. 1a shows a presence pattern of foreign substances on the back surface of the wafer. In order to produce the semiconductor elements on the front surface of the wafer, the processes of exposing the front surface of the wafer (photolithography), of etching the front surface, of deposition to the front surface, and polishing to the front surface should be performed repeatedly. In all processes, the wafer is firmly fixed to the wafer holding chuck by a vacuum or electrostatic force, to maintain a very flat front surface. The wafer is fixed to the wafer holding chuck, and then only more precise semiconductor processes for the front surface of the wafer can be performed. During iterative semiconductor processes, contaminations are consistently generated on the back surface of the wafer. In particular, a degree of the contamination to the outer portion of the back surface of the wafer is higher than a degree of the contamination to the center portion of the back surface of the wafer, because the outer portion is easily exposed to the wafer process environment. As shown in FIG. 1a, When foreign substances are adhered to the back surface (F2) of the wafer (W), especially, the outer portion (P) of the back surface (F2) of the wafer (W) which is fixed to the wafer holding chuck (C), the front surface (F1) of the wafer (W) becomes non-uniform and local height variations are generated on the front surface (f1) of the wafer (W). If the exposure process is performed in condition that such a local height variation is occurred, defocusing phenomena that the light is out of the focus onto the front surface (F1) of the wafer (WI) is generated due to height variation. The defocusing phenomena cause poor patterning during the semiconductor process, which lowers the production yield of the semiconductor die. As recent semiconductor processes has been more extremely precise, the depth of focus of the light source in the exposure process (DOF; Depth Of Focus), that is the depth of focus tolerance has lowered below 100 nm. Therefore, when height deviation (H) of the wafer is more than 100 nm, the precise focusing on the intended location of the front surface of the wafer (F1) is impossible. Therefore, if there are the fine foreign substances (P) having sizes of more than several hundred nm or more adhered on the back surface (F2) of the wafer (W), the height deviation occurs on the front surface (F1) of the wafer (W). If the height deviation is more than 100 nm, the exact focusing on the front face of the wafer, defects of the patterns on the front surface (F1) of the wafer (W) occurs. Therefore, in order to precisely form the fine pattern of several tens of nm, few hundred nm or more fine foreign substance (P) should be removed from the back surface of the wafer, and then only, it is possible to produce a semiconductor with no reduction in yield. Also, during polishing process after deposition process, the protruding portions on front surface of the wafer due to the foreign substances (P) on the back surface of the wafer (W) generates a local over-polishing phenomenon, and, this results in a polishing defect, which lowers the yield. To remove fine foreign substances, which have effects on semiconductor yield, from the back surface (F2) of the wafer (W), the cleaning on the back surface (F2) of the wafer (W) has been performed by wet cleaning method by using spraying high pressure water, using a megasonic waves or a soft rotation brush. However, it is difficult to ensure the effective cleaning, because the foreign substances (P) are adhered to the back surface (F 2) of the wafer (W) with a very large force and the particle size of the foreign substance is very small. It is also difficult to selectively and locally clean the outer part of wafer (W) which the largest deviation occurs among the portions of the wafer. Therefore, there are needs for method solving these various problems in the art.

FIG. 1b shows a pattern of contaminants present on the wafer edge. In order to produce the semiconductor elements on the front surface of the wafer, the processes of exposing the front surface of the wafer (photolithography), of etching the front surface, of deposition to the front surface, and polishing to the front surface should be performed repeatedly. In order to produce only one of the semiconductor devices, the above processes should be repeated for about 500 times to form the semiconductor device comprising a few dozen layers of deposition films laminated. These variable deposition films (amorphous-Si, poly-Si, SiO₂, Si₃N₄, TiN, Al, Cu, etc.) are laminated on the wafer during the repetitive semiconductor processing. On these deposition films, a photo resist is formed resist in a photo process, and then, etching, deposition and polishing, etc are performed. Because of the surface tension at the edge of the wafer, various contaminants such as the deposition layer, PR, etching residues and particles are deposited in a convex form during the above processes. Also, after wafer polishing, fine slurry particles used in the polishing are intensively distributed at the wafer edge. Thus, uneven and non-planar surface occurs aggressively in about 1 mm area around the wafer edge. Such a contaminants act as a particle in the semiconductor manufacturing process to lower the production yield of the semiconductor. According the size of the semiconductor wafer increases recently, removing foreign substances on the edge of the wafer is considered to be very important. Various methods for removing various contaminants present on the edge of the wafer have been tried. Among the conventional method, there is a wet chemical method for removing the foreign substance and PR from the edge of the wafer by spraying a strong acid or alkali solution to the edge of the wafer, it is fundamentally difficult to selectively clean only a specific area of the wafer edge, there are a lot of concerns that the drug could damage to the wafer device, and, it is difficult to comprehensively remove the various materials present at the edge. Further, the conventional wet chemical method has a disadvantage that it takes a long time, because it needs the rinse and dry cleaning necessarily. Alternatively, there is a method for cleaning the edge of the wafer by using plasma, which is not possible to clean the specific area of the edge precisely, and which affluences charging effects to the wafer by strong plasma formation. Another technology is a technology for evaporating and removing contaminants by directly radiating a UV laser beam to the wafer edge. This technique is disclosed in U.S. Pat. No. 7,514,015 and U.S. Pat. No. 566,979 by “UVTech”. However, that disclosed technology has a disadvantage that cannot prevent re-contamination on the wafer surface by the excessive dusts generated during the laser beam cleaning. Although it is possible to collect the dust particles generated during the laser beam cleaning with a powerful suction device. The separation speed and the separation force of the dust particles generated during the laser beam cleaning are too fast and too strong to remove completely the dust particles by an air trapping method. Therefore, there is a need for methods of solving these various problems in the art.

### DISCLOSURE

### Technical Problem

The object of the present invention is to provide a technique for cleaning a back surface of a wafer, which can effectively clean the foreign substances on the back surface of the wafer by rotating the wafer in condition that at least an outer portion of the back surface of the wafer is exposed and radiating a laser beam of the pulse-wave form on the exposed outer portion of the wafer.

### Technical Solution

A wafer back surface cleaning apparatus according to one aspect of the present invention, comprises a rotating unit for rotating the wafer in condition that the outer portion of the back surface of the wafer is exposed; a laser beam irradiating unit for irradiating a pulse-wave laser beam onto the outer portion of the back surface of the wafer, wherein the pulse-wave laser beam irradiated location on the wafer changes depending on the rotation of the wafer; and a dust collecting unit for collecting dust separated from the outer portion of the back surface of the wafer in the result of the irradiation of the pulse-wave laser beam.

A wafer back surface cleaning apparatus according to another aspect of the present invention, comprises a laser beam generating part for generating a pulse-wave laser beam having pulse width of 1 msecond or less; a laser beam transmitting part for transmitting the pulse-wave laser beam; a laser beam irradiating part for irradiating the pulse-wave laser beam transmitted through the laser beam transmitting part; a wafer supporting part for supporting the wafer so that the front surface of the wafer faces upwards and the back surface of the wafer faces downwards, while allowing the exposure of the back surface of the wafer to the pulse-wave laser beam generated from the lager generating part.

A wafer edge cleaning apparatus according to the present invention provides comprises a liquid ejecting unit for ejecting liquid onto a surface of a wafer so that a liquid film can be formed on the surface; a wafer rotating unit for rotating the wafer so that the liquid film can be extended to the edge of the edge; a laser beam irradiating unit for irradiating a laser beam to the foreign substance adhered to the edge of the wafer through the liquid film.

### Advantageous Effects

The wafer back surface cleaning technique according to the present invention can efficiently and quickly remove the fixative foreign substance which cannot easily is removed with the conventional wet cleaning method. The wafer back surface cleaning apparatus is modularized and can be provided in the conventional wet cleaning equipment as a module. If so, the weakness of the conventional wet cleaning method such as insufficient detergency can be overcome.

Also, a wafer edge cleaning technique using liquid film and laser does not damage the elements on the surface of the wafer, while the conventional chemical wet cleaning technique damages the elements on the surface of the wafer. Because the wafer edge cleaning technique according to the present invention irradiates the laser beam to the contaminants adhered to the edge of the wafer through the liquid film, the problems such thermal damage of the wafer and recontamination of the wafer can be overcome.

### DESCRIPTION OF DRAWINGS

Figure a is a diagram illustrating the pattern and the resulting problems of foreign substance adhered to the back surface of the wafer.

FIG. 1b is a diagram illustrating the pattern and the resulting problems of foreign substance adhered to the edge of the wafer.

FIG. 2 is a diagram illustrating an apparatus for cleaning the back surface of the wafer and a method for cleaning the back surface of the wafer by using the apparatus according to the first embodiment of the present invention.

FIG. 3 is a diagram for illustrating an apparatus for cleaning the back surface of the wafer and a method for cleaning the back surface of the wafer by using the apparatus according to the second embodiment of the present invention.

FIGS. 4 and 5 are diagrams for explaining a technique of cleaning the back surface of the wafer more effectively by using a laser beam cleaning technique and a wet cleaning technique together.

FIG. 6 are images for showing the effect of removing foreign substance adhered to the back surface of the wafer by the laser.

FIG. 7 is a diagram illustrating apparatus for cleaning the surface of the wafer according to the third embodiment of the present invention.

FIG. 8 is a diagram illustrating apparatus for cleaning the surface of the wafer according to the fourth embodiment of the present invention.

FIG. 9 is a diagram illustrating a pulse-wave characteristics of the laser beam irradiated to the back surface of the wafer according to the fourth embodiment of the present invention.

FIG. 10 is a diagram illustrating a configuration to obtain the information about the foreign substances on the wafer back surface of the particle and then performing the local cleaning of the foreign substances by using the information according to the fourth embodiment of the present invention.

FIG. 11 is a diagram illustrating an apparatus and method for cleaning the edge of the wafer according to a fifth embodiment of the present invention.

FIG. 12 is a diagram for explaining a configuration of a wafer rotating unit preferably employed in the apparatus for cleaning the edge of the wafer according to the fifth embodiment of the present invention.

FIG. 13 is a diagram illustrating an apparatus for cleaning the edge of the wafer according to the sixth embodiment of the present invention.

FIG. 14 is a diagram illustrating an apparatus for cleaning the edge of the wafer according to the seventh embodiment of the present invention.

### BEST MODE

Hereinafter, the preferred embodiments of the invention with reference to the accompanying drawings will be described.

As shown FIG. 2, a wafer back surface cleaning apparatus according to a first embodiment of the present invention comprises a rotating unit 100 for rotating a wafer (W) in condition that the outer portion of the back surface is exposed, a the laser beam irradiating unit 123 for irradiating a pulse-wave laser beam onto the outer portion of the back surface and a dust collection unit 140 for collecting foreign substances (P) separated from the outer portion of the back surface (F2) due to the irradiation of the pulse-wave laser beam. Even if the position of the laser beam irradiating unit 123 is fixed, The laser beam irradiating unit 123 can irradiate the pulse-wave laser beam to the variable locations on the wafer (W) according to the rotation of the wafer (W) by the rotating unit 100.

The rotating unit 100 and the laser beam irradiating unit 123 and the dust collecting unit 140 may be incorporated into one module, in this specifications, such a module is referred to as “laser beam cleaning module”. The laser beam irradiating unit 123 comprises a laser beam generating part 110 for generating a laser beam, a laser beam transmission part 120 for transmitting the laser generated by the laser beam generating part 110, and a laser beam irradiating part 130 for focusing and irradiating the laser beam transmitted through the laser beam transmission part 120 onto the outer portion of the back surface (F2) of the wafer (W). The laser beam generated from the laser beam generating part 110 is guided to the outer portion of the back surface (F2) of the wafer (W) through the laser beam transmission part 120 and the laser beam irradiating part 130. The laser beam transmitted through the laser beam transmission part 120 and passing through at least one lens of the laser beam irradiating part 130, of which shape and size are adjusted suitably, is irradiated to foreign substances onto the outer portion of the back surface (F2) of the wafer (W). The cleaning area by laser beam irradiation can be determined by transferring the laser beam irradiating part 130 toward the center of the wafer (W). The foreign substances (P) adhered to the back surface of the wafer are concentrated within about 10 mm from the edge. Accordingly, if the cleaning area is determined within 10 mm from the outer periphery portion, the laser beam cleaning can be carried out very quickly. Of course, the cleaning area can be increased or decreased as needed. As well-shown in FIG. 2, in this embodiment, the wafer holding chuck (C) provided at the distal end of the shaft in the rotating unit 100 holds the center portion of the back surface (F2) of the wafer (W) for example by using a vacuum to fix the wafer (W). Thus, the peripheral portion around the center portion of the back surface of the wafer (W) covered by the wafer holding chuck (C) is exposed to the laser beam irradiating unit 123 which is located below the wafer holding chuck (C). The material for the wafer holding chuck (C) has a lower hardness than the hardness of the wafer to prevent the wafer from being damaged when the fixing chuck fixes wafer (W). It is preferable that the wafer holding chuck (C) is the vacuum chuck. Larger the diameter of the wafer holding chuck (C) is, it is more limited to increase the cleaning area for the back surface of the wafer (W). Accordingly, it is preferable that the wafer holding chuck (C) should be prepared with as small a diameter. Usually the diameter of the wafer holding chuck (C) is preferably not more than 200 mm. In order to clean the overall outer portion of the back surface (F2) of the wafer (W) fixed to the wafer holding chuck (C), the wafer (W) should be rotated in the direction of arrow a1 by using the rotating unit 100. It is preferable that the number of revolutions of the wafer holding chuck (C) by the rotating unit 100 is not more than 1000 rpm. Although the laser beam irradiating part 130 does not turn, the laser beam irradiating part 130 can irradiate the laser beam onto the back surface of the wafer (W) in the same pattern as for the turning around center of the wafer (W). The laser beam irradiating unit 130 can irradiate the laser beam in condition that the laser beam irradiating part 130 is fixed or in condition that the laser beam irradiating part 130 is moved in the radial direction of the wafer (W). It is preferable that the pulse-wave laser beam generated by the laser beam generating part 110 has pulse width less than 1 msecond in order to cleaning the back surface (F2) of the wafer (W) effectively, and energy of less than 100 mJ for minimizing thermal damages to the wafer (W). In addition, the wavelength of the laser beam is preferred of ultraviolet or visible light, i.e. 200 nm˜800 nm of which energy can be absorbed effectively to the silicon (Si) wafer. The pulse-wave laser beam from the laser beam generating part 110 are transmitted to the laser beam irradiating part 1300 near the back surface (F2) of the wafer (W) through the laser beam transmission part 120. It is preferable that an optical fiber is used as the laser beam transmission part 120 for solving the problem such as alignment of the laser beam. Alternatively, the reflection mirror in place of the optical fiber can transmit the pulse-wave laser beam in the vicinity of the back wafer (W) as the laser beam transmission part. At this time, it has the advantage that a multi-mode fiber used as the laser beam transmission part 120 can transmit the pulse-wave laser beam to the laser beam irradiating unit 130 in a uniform energy distribution. The laser beam irradiating part 130 includes a collimation lens 1302 for making the laser beam spreading from the end of the laser beam transmission part 120, mores specifically the optical fiber into parallel laser beam, and a irradiation lens 1303 for changing the laser beam size as a predetermined size and radiating the size changed laser beam on the back surface (F2) of the wafer (W). The diameter (D) of the final laser beam irradiated onto the back surface (F2) of the wafer (W) is adjustable by changing the distance (L) between the laser beam irradiating part 130 and the wafer (W). It is preferable that the distance (L) between the laser beam irradiating part 130 and the wafer (W) is more than 50 mm, because there is a possibility that the irradiation lens 1303 would be contaminated by the dust generated during the laser beam cleaning, when the laser beam irradiating part 130 is too close to the wafer (W). Because the size of foreign substance particle on the back surface is up to several dozen um, it is enough that the diameter (D) of the irradiating laser beam is less than 1 mm. It is preferable that the energy density of the laser beam for the laser beam cleaning is preferable 5 J/cm² or less. If the energy density of the laser beam is more than 5 J/cm², that may cause damage to the base material of the back surface (F2) of the wafer (W). Pulses of the laser beam irradiated to the foreign substance is preferably not more than typically 10 pulses in the same position. If more than 10 pulses, that may result in damage to the back surface of the wafer due to thermal accumulations. The dust generated during cleaning the back surface (F2) of the wafer (W) should be removed as much as possible it can be collected, because the optical system and the peripherals of the laser beam irradiating unit 123 may be contaminated by the dust. In order to prevent the contamination of the optical system and the peripherals by the dust, the dust collecting unit 140 is arranged near the laser beam irradiating area 140. The dust collection unit 140 includes a dust collecting part 1402 and the dust aspirator 1401. The dust aspirator 1401 may include a vacuum pump or fan blower to suck the dust. The dust collecting part 1402 collects and captures the sucked dust.

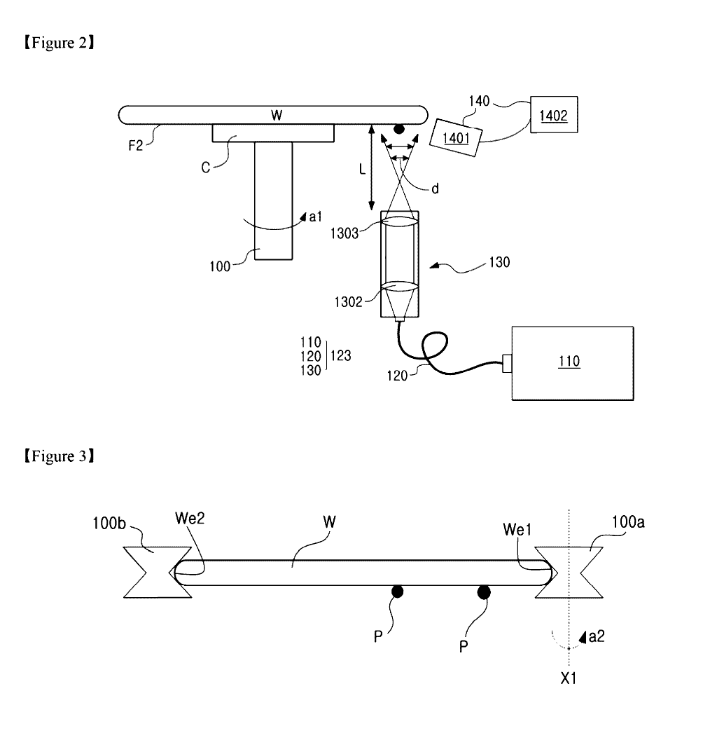

As shown in FIG. 3, a wafer back surface cleaning apparatus according to a second embodiment of the present invention comprises rotating unit including a first support element 100a and a second support element 100b for rotating the wafer W in condition that the back surface of the wafer is exposed. The first support element 100a is connected to the driving means including motor and is driven and is rotated in the direction of arrow a2 around the axis X1. The first support element 100a includes a roller, which supports the edge or the periphery of the wafer W, driven by the driving means. The second support element 100b includes another roller with idle type, which supports the edge or the periphery of the wafer W and rotates idly. The second support element 100b is not connected with any drive means, and rotates only depending on the rotational force of the wafer (W) rotated by the first support element 100a. A first support element 100a and the second support element 100b may include a support groove having for example a V shape groove on the outer peripheral surface respectively to be able to support the edge portion (We1, We2) of the wafer (W). This type of rotating unit has an advantage that can substantially fully expose the back surface (F2) of the wafer (W), so that the back surface (F2) of the wafer can be cleaned as a whole. Yet, if the rotating unit of this embodiment is employed, a new problem occurs that new fine foreign substances may be generated between the edge contact surface of the wafer (W) and the first and second support elements 100a, 100b. For the preparation to said problem, it is preferred that a material for the first and second supporting elements 100a and 100b is selected to minimize foreign substance generation by the friction between the wafer and the first and second supporting elements 100a and 100b.

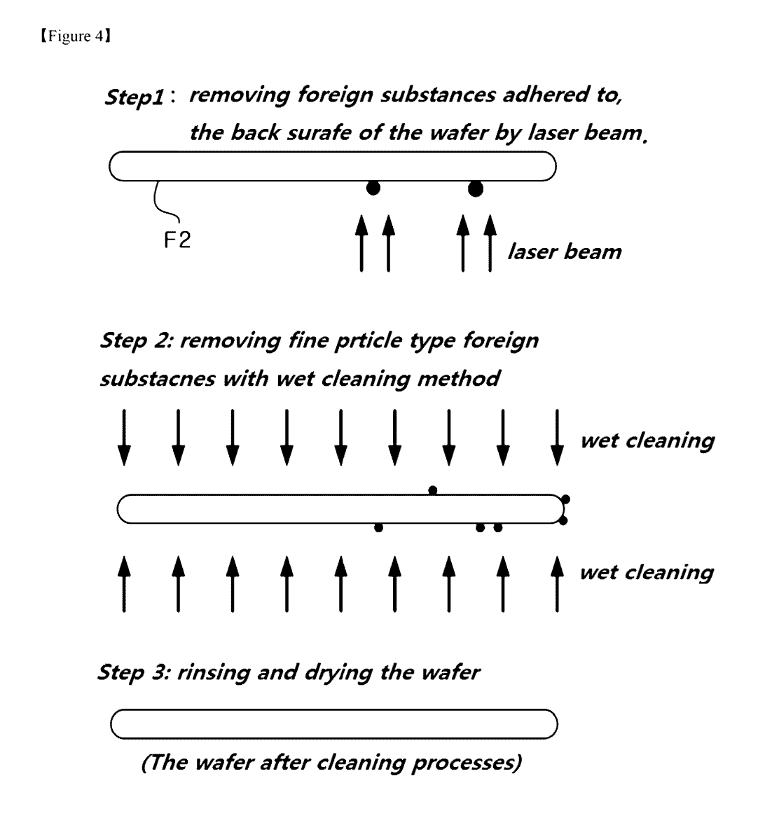

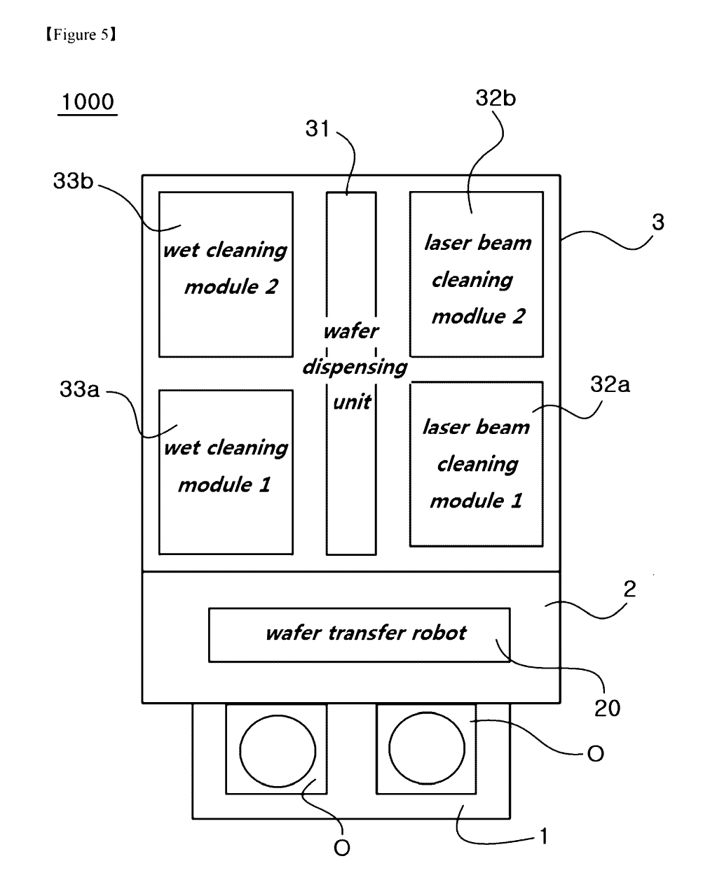

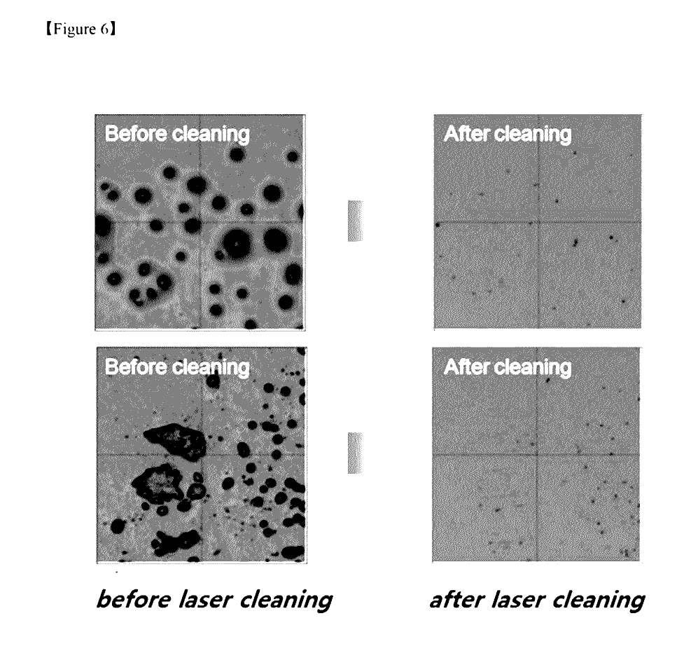

As shown in FIG. 4, the method for cleaning the back surface of the wafer comprises generally a first step, a second step and a third step. The first step comprises irradiating a laser beam onto the large scale foreign substance adhered to the back surface (F2) of the wafer, in particular, the outer portion of the back surface (F2) of the wafer, to remove the foreign substance. At this time, by irradiating the laser beam on the back surface (F2) of the wafer while rotating the wafer, the substantially full area cleaning for the back surface (F2) of the wafer by using the laser beam can be achieved. If the laser beam irradiated on the back surface of the wafer without rotating the wafer, it will be difficult for the overall laser beam cleaning for the back surface (F2) of the wafer, because the shape of the laser beam irradiation area is determined as a spot shape. As described in detail above, the foreign substance separated from back surface of the wafer by the laser beam is removed as much as possible by the dust collection unit permanently. For the laser beam cleaning in the first step, the laser beam cleaning module which incorporates parts described in the first embodiment or the second embodiment can be used. The second step comprises process for removing very fine sizes of particles, which may be remaining on the back surface or the edge of the wafer, with wet cleaning after the laser beam cleaning process. Although enough strong dust collector is used, residues comprising very fine particles more than size of 1 um are present around the cleaning area after laser beam cleaning process. Also, if the wafer (W) is rotated while its edge portion is gripped as in the second embodiment shown in FIG. 3 (We1, We2), due to the contact between the side surface of the wafer (W) and the support elements, the fine contaminant particles are generated and adhered to the side surface of the wafer (W). The fine particles of contamination which occurs during the laser beam cleaning process can be removed completely by using the known wet cleaning comprising for example water jet, megasonic or brush function. The wet cleaning of the second step is carried out in the wet cleaning module isolated from the laser beam cleaning module in the equipment comprising the wet cleaning module and the laser beam cleaning module, wherein, the wet cleaning module comprises the conventional wet cleaning function (which comprises water jet, megasonic or brush functions). Finally, the third step comprises processes for rinsing and drying the wafer after the second step, i.e. the wet cleaning step. The processes for rinsing and drying the wafer can be done by a spin method performed in the general wet cleaning process. As shown in FIG. 5, the wafer cleaning system 1000 comprises a wafer loading port 1, a wafer transfer part 2 and a wafer cleaning part 3. A wafer carrier (O) is mounted on the wafer loading port 1, wherein the wafer carrier (O) accommodates a plurality of wafers. A wafer transfer robot 20 is arranged at the wafer transfer part 2, wherein the wafer transfer robot 20 takes out the wafer from the wafer cleaning part 3 and then transfer the wafer (W) to the wafer cleaning part 3 when the door of the wafer carrier (O) mounted on the wafer loading port 1 is open. The wafer cleaning part 3 is a part for performing the laser beam cleaning and the wet cleaning for the wafer transferred from the wafer transfer robot 20. The wafer cleaning part 3 includes a wafer dispensing unit 31, first and second laser beam cleaning modules 32a, 32b and, first and second wet cleaning module 33a, 33b. Said wafer dispensing unit 31 performs an operation to receive the wafers and load the wafers the first and second laser beam cleaning module 32a, 32b respectively and another operation to unload the wafers of which the back surface had been cleaned. Preferably, Said wafer dispensing unit 31 supplies the first wafer to the first laser beam cleaning module 32a, so that the first wafer can be cleaned by the laser beam. During the first laser beam cleaning module 32a cleans the back surface of the wafer, Said wafer dispensing unit 31 supplies the second wafer secondly to the second laser beam cleaning module 32a, so that second wafer can be cleaned by the laser beam. Thus, since two or more laser beam cleaning modules are provided in the wafer cleaning part 3, the cleaning throughput for the wafer can be increased. After the foreign substances strongly adhered to the back surface of the wafer is removed by the first and second laser beam cleaning module 32a or 32b, if it needs to precisely clean the fine particles of the dust, in particular, generated during the laser beam cleaning, the wafer dispensing unit 31 transfers the wafers to the first and second wet cleaning modules 33a, 33b, which are located opposite to the first and second laser beam cleaning modules 32a, 32b. The first and second wet cleaning module 33a, 33b can clean the back surface and the front surface of the wafer by using conventional methods such as a water jet, megasonic, brush or the like. Of course, in the case of requesting the extreme cleanliness of the wafer, the wet cleaning may be used as an optional process in addition to the laser beam cleaning process belonging to dry process. Adversely, the existing wet cleaning apparatus may be equipped with a laser beam cleaning module. In this case, if there is a need to remove strongly fixative particles, the laser beam cleaning process can be used as an optional process. In order to increase the cleaning throughput, two or more quantities of the cleaning modules are required. FIG. 6 shows that the fixative foreign substances on the back surface of the wafer are removed effectively by the laser beam. Such a fixative foreign substance cannot be removed by a conventional wet cleaning method. As a result, the present invention provides a method for effectively removing fixative foreign substances present on the back surface of the wafer by using a laser beam. Also, according to the present invention, it is possible to clean the back surface of the wafer at a very high speed. Also, according to the present invention, the cleaning processes are simple. Also, according to the present invention, the wafer back surface cleaning apparatus can be achieved with very small size. The present invention has an advantage of being able to locally clean some perimeter areas of the wafer. Also, the wafer back surface cleaning apparatus according to the present invention includes laser beam cleaning means applied in the form of a module and is able to overcome the disadvantages the conventional wet cleaning system insufficient to remove the fixative foreign substance adhered to the back surface of the wafer.

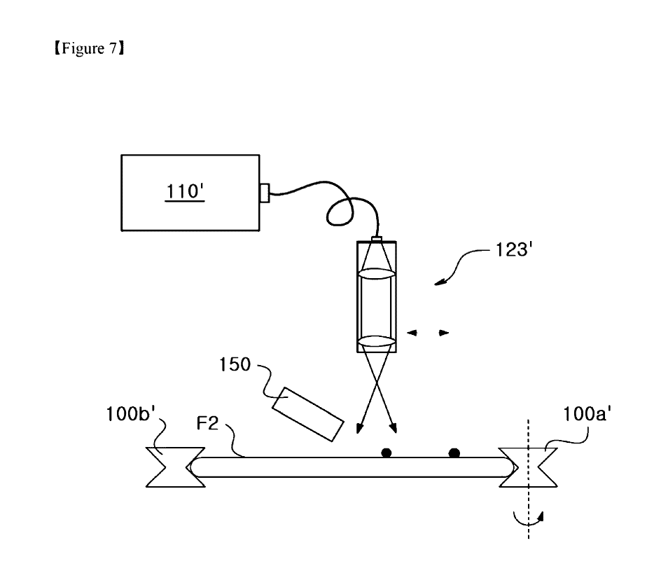

As shown in FIG. 7, an wafer back surface cleaning apparatus according to a third embodiment of the present invention comprises a rotating unit 100 for rotating the wafer (W) in condition that the back surface of the wafer is exposed upwardly, a the laser beam irradiating unit 123 for irradiating a pulse-wave laser beam onto the back surface from the position above the back surface. The wafer back surface cleaning apparatus according to the third embodiment of the present invention comprises the rotating unit 100 (including a first support element 100a′ and a second support element 100b′ which support and rotate the wafer while exposing the back surface (F2) of the wafer (w) upwardly, instead of the rotating units in the embodiments previously described which supports and rotates the wafers while exposing the back surface (F2) of the wafer (w) downwardly. If the rotating unit 100 supports and rotates the wafer while exposing the back surface (F2) of the wafer (w) upwardly, the foreign substance with dust state separated from the wafer back surface (F2) is almost left on the back surface of the wafer (F2). Thus, the wafer back surface cleaning apparatus according to this embodiment further comprises a liquid ejecting unit 150 for removing foreign substances remaining on the back surface (F2) of the wafer by spraying liquid at a high pressure onto the back surface (F2) of the wafer. The liquid ejecting unit 150 may comprise a liquid ejecting nozzle movable above the back surface (F2) of the wafer. Preferably, the liquid discharge nozzle can be movable back and forth linearly along the radial direction of the wafer (W). Because the wafer back surface cleaning apparatus according to this embodiment uses the liquid ejecting unit 150, it is possible to omit the dust collecting unit according to the previous embodiment which may be used for dust and foreign substance trapped. Also, because the liquid ejecting unit 150 can remove any remaining foreign substance on the back surface of the wafer by wet method, it is possible to omit or simplify extra wet cleaning processes after the laser beam cleaning, according to a liquid ejecting condition and the type of liquid in the liquid ejecting unit 150. The configurations not described specifically in the specifications of this embodiment can follow as the previous embodiment.

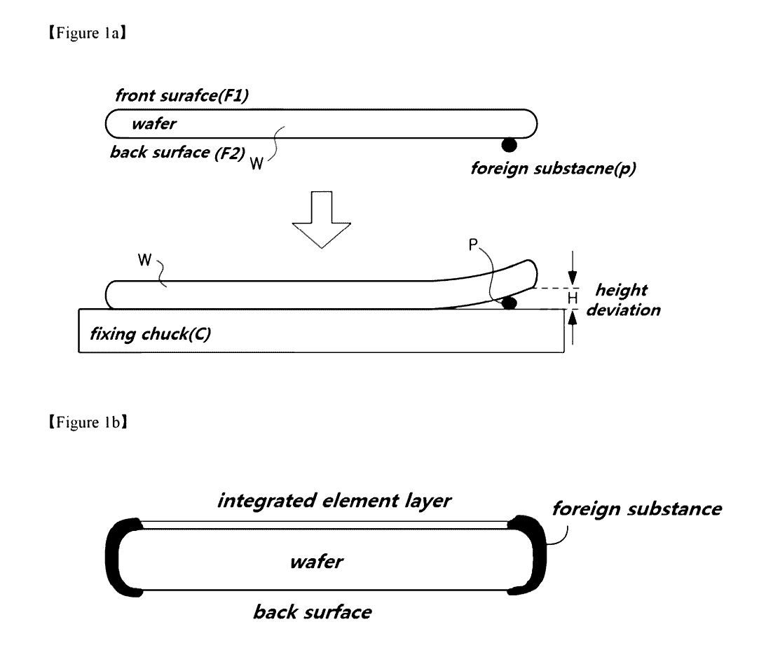

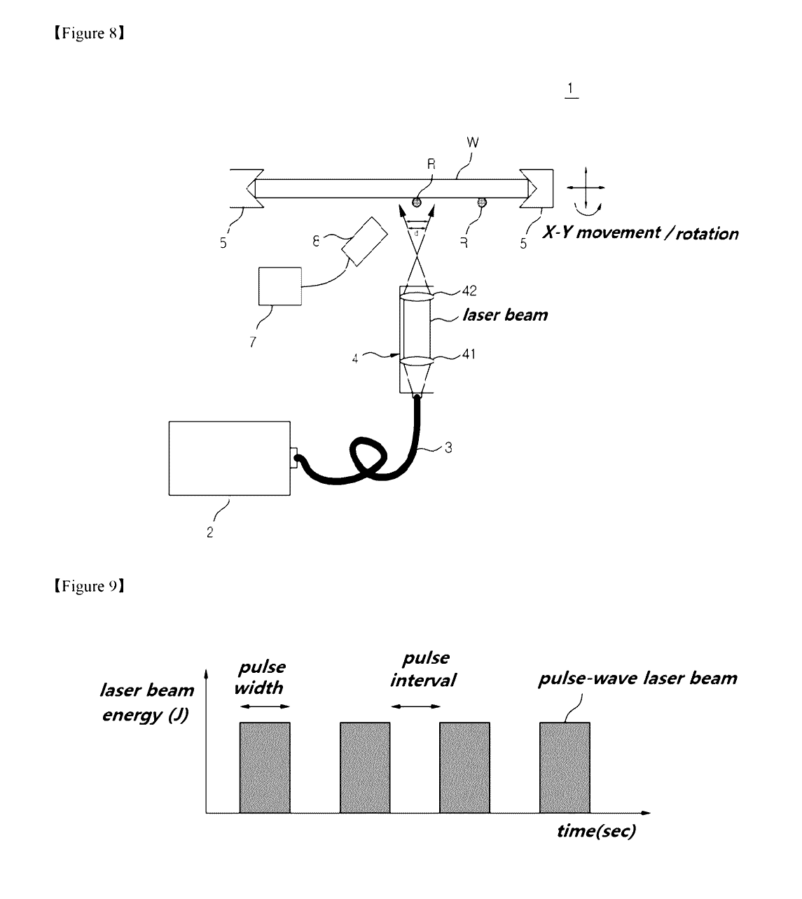

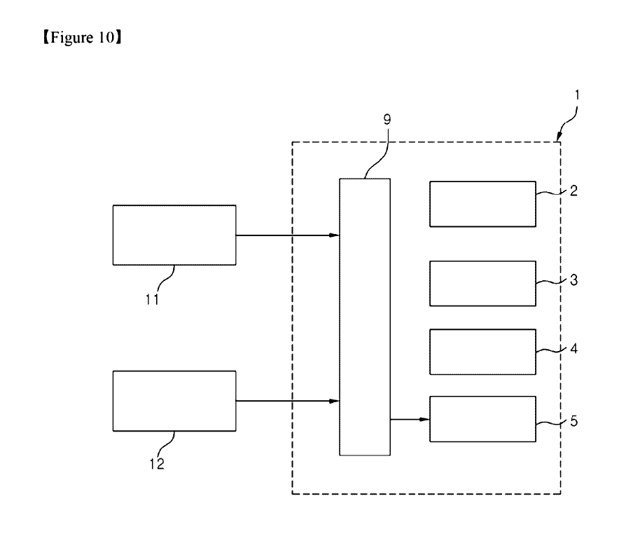

Hereinafter, the descriptions will be made as to the wafer back surface cleaning apparatus and a cleaning method according to a fourth embodiment of the present invention. In the below descriptions, the different things with above described embodiments will be explained in detail. But, relating to the same or similar things with the above described embodiments, the detailed descriptions will be omitted to avoid duplication. Referring to FIG. 8, you can see an apparatus for dry-cleaning fine foreign substances (R) adhered to the back surface of the wafer by a laser beam, i.e. the wafer back surface dry cleaning apparatus 1. The wafer back surface dry cleaning apparatus comprises a laser beam generating part 2 for generating a pulse-wave laser beam, a laser beam irradiating part 4 for irradiating the pulse-wave laser beam onto the back surface of the wafer (W), a laser beam transmitting part 3 for transmitting the laser beam generated from the laser beam generating part 2 to the laser beam irradiating part 4, and a wafer supporting part 5 for supporting the wafer (W) so that the back surface of the wafer can be exposed to the pulse-wave laser beam irradiated from the laser beam irradiating part 4. In the description of this embodiment, the term “exposed” indicates that the pulse-wave laser beam reaches the back surface of the wafer (W). That is, even if there are any of the objects between the back surface of the wafer 4 and the laser beam irradiating part 4, if the object is capable of transmitting the pulse-wave laser beam, we can say that the back surface of the wafer (W) is exposed to the pulse-wave laser beam. As mentioned above, the pulse-wave laser beam generated in and oscillated from the laser beam generating part 2 is derived closer to the back surface of the wafer (W). The laser beam irradiating part 4 is oriented toward the back surface of the wafer (W), controls the laser beam transmitted through the laser beam transmitting part 3 with the appropriate type and size, and irradiates it to the foreign substance (R) present on the back surface of the wafer. The wafer supporting part 5 comprises a fixing clamp for fixing the wafer by holding the edge of the wafer, so as to expose the back surface of the wafer (W) to the pulse-wave laser beam irradiated from the laser beam irradiating part 4. In the description of this embodiment, the indication number “5” is used as both the indication number for the wafer supporting part and the indication number for the fixing clamp. The fixing clamp 5 may be made of a material having a smaller hardness than the hardness of the wafer (W) in order to prevent damages to the wafer (W) when the fixing clamp 5 fixed the wafer. In addition, the clamp 5 is connected to a XY movable and rotatable stage (not shown). Therefore, foreign substances (R) existing in various locations on the back surface of the wafer (W) can be removed effectively and accurately by the pulse-wave laser beam locally irradiated from the laser beam irradiating unit according to the adjustment of the XY moving or rotating movement of the wafer (W). Also, the laser beam generating part 2 preferably may generate a laser beam having pulse width of 1 msecond or less for an effective removal of the foreign substances from the back surface of the wafer. The distance between the neighboring pulses is preferably not less than 100 usecond to minimize heat accumulation applied to the wafer. In addition, it is preferable that the energy of each pulse is at least 1 mJ. Also, it is preferable that the wavelength of the laser beam is 300-75 nm visible spectrum. Referring to FIG. 8 again, the pulse-wave laser beam from the laser beam-generating part 2 is guided to near the back surface of the wafer (W) through the laser beam transmitting part 3. The laser beam transmitting part 3 includes an optical fiber, wherein the optical fiber can be advantageously used to for solving the problem such as the alignment of the laser beam. It is preferable that the optical fiber is a multi-mode fiber. The multi-mode fiber has an advantage of the ability to deliver a pulse-wave laser beam with a uniform energy distribution to the laser beam irradiating part 4. However, the reflection mirror part can be employed as the laser beam transmitting part 3 for guiding the laser beam near the back surface of the wafer as described above. The laser beam irradiating part 4 comprises a collimation lens 41 for making the laser beam spreading from the end of the laser beam transmitting part 3, mores specifically the optical fiber into parallel laser beam, and a irradiation lens 42 for making the beam size of the laser beam reduced and radiating the size-reduced laser beam on the back surface of the wafer (W). The diameter (d) of the final pulse-wave laser beam irradiated on the back surface of can be adjusted by varying the distance (L) between the laser beam irradiating part 42 and the wafer (W). If the laser beam irradiating part 4 is positioned too close to the wafer (W), the lens 40 is likely to be contaminated by the dust generated during cleaning. Therefore, It is preferable that the distance (L) between the wafer (W) and the irradiating lens 40 maintains with 50 mm or more. Because, the size of the target foreign substance for removal on the back surface of the wafer (W) is up to several tens of urn, the sufficient cleaning area can be guaranteed by irradiating the laser beam having the diameter (D) less than 1 mm on the back surface of the wafer (W). It is preferable that the average energy density of the laser beam for the washing is 5 J/cm² or less. The laser beam of which energy density is more than more than 5 J/cm², causes damage to the base material of the wafer. Pulses of the laser beam irradiated to the foreign substance are preferably not more than 10 pulses at the same irradiated location. The laser beam in excess of 10 pulses may cause damage to the base material of the wafer back surface due to heat accumulation. In addition, in order to collect the dust generated during cleaning the back surface of the wafer (W), the wafer back surface dry cleaning apparatus 1 comprises a dust collector 7 and a dust collecting part 8 connected to the dust collector 7. Because the dust generated during the dry cleaning with the laser beam may contaminate the optical system and the devices surrounding that system, it should be collected and removed as much as possible. A vacuum pump or fan flower can be employed as the dust collector 7. Because the dust collecting part 8 is movably disposed in the vicinity of the back surface of the wafer (W), it is possible to effectively collect the dust generated during cleaning the foreign substance with laser beam. FIG. 10 shows block diagram of the dry cleaning apparatus. The dry cleaning apparatus is constructed to find the exact position of the foreign substance (R; referring to FIG. 8) present on the back surface of the wafer (W) and to irradiate a pulse-wave laser beam to the foreign substance. Thus the dry cleaning apparatus has more increased removal efficiency for the foreign substance. Referring to FIG. 10, the wafer back surface dry cleaning apparatus 1 further includes a controller 9 for controlling the X-Y movement and the rotational movement of the wafer support 5, so that the laser beam irradiated from the laser beam irradiating part 4 can be matched to the foreign substance on the back surface of the wafer. Alternatively, the movement of the laser beam irradiating part 4 can be controlled by the controller 9, so that the laser beam can be matched to the foreign substance on the back surface. The controller needs the information about the location of the foreign substance on the back surface of the wafer (W), in order to perform the control of matching the laser beam to the foreign substance on the back surface of the wafer (W). Two kinds of devices are used to obtain the information about the location of the foreign substance on the back surface of the wafer (W). One of these is the exposure device 11, and the other is a wafer back surface particle inspection system 12. The exposure device 11 performs accurate scanning with respect to the front surface of the wafer (W) for the accurate exposure process and can obtain accurate measurement of the position, even If there is a relatively large foreign substance on the back surface of the wafer (W) (see FIG. 1) and a wafer surface height (H, see FIG. 1) variation has been occurred. The wafer back surface particle inspection system 12 irradiates a laser beam on the back surface. At this time, if the foreign substance present on the back surface, the scattering of the laser beam is generated. The wafer back surface particle inspection system 12 can accurately measure the scattered amount of the laser beam to precisely obtain the present location and the size of the foreign substance. As mentioned earlier, the wafer back surface dry cleaning apparatus 1 according to this embodiment can irradiate the laser beam locally to the back surface of the wafer (W). Thus, the wafer back surface cleaning apparatus can clean only the foreign substance selectively and quickly if knowing the exact location of the foreign substance. The exposure device 11 or the wafer back surface particle inspection system 12 provides the data about the location of the foreign substance on the wafer back surface to the controller 9 as a file, and the controller 9 moves the stage connected to the wafer supporting part 5 so as to match the laser beam irradiation location and the location of the foreign substance. By doing so, the dry cleaning apparatus can remove only the foreign substance selectively. Selective and local cleaning capability such as aforesaid is the capability which only the dry cleaning method can have, and its advantage is of being able to remove only the aimed foreign substance on the back surface of the wafer. As above, the dry cleaning technique is provided, which can effectively and quickly remove fine foreign substances adhered to the back surface of the wafer with the laser beam. Also, there are advantages that processes for the dry cleaning are simple and the dry cleaning apparatus can be made with very small size.

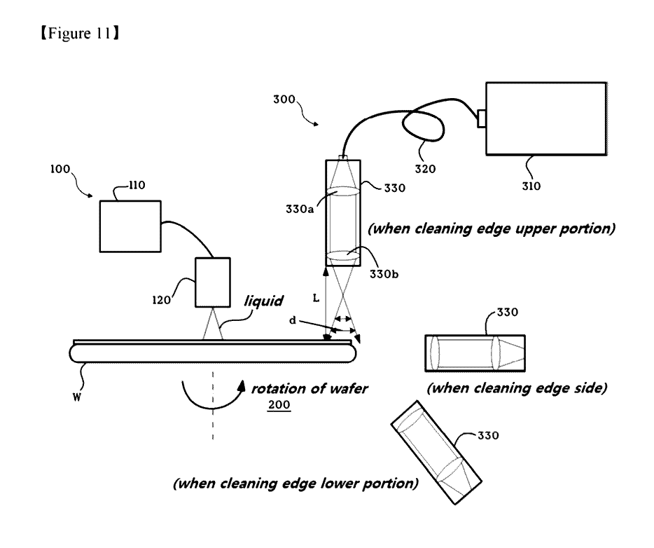

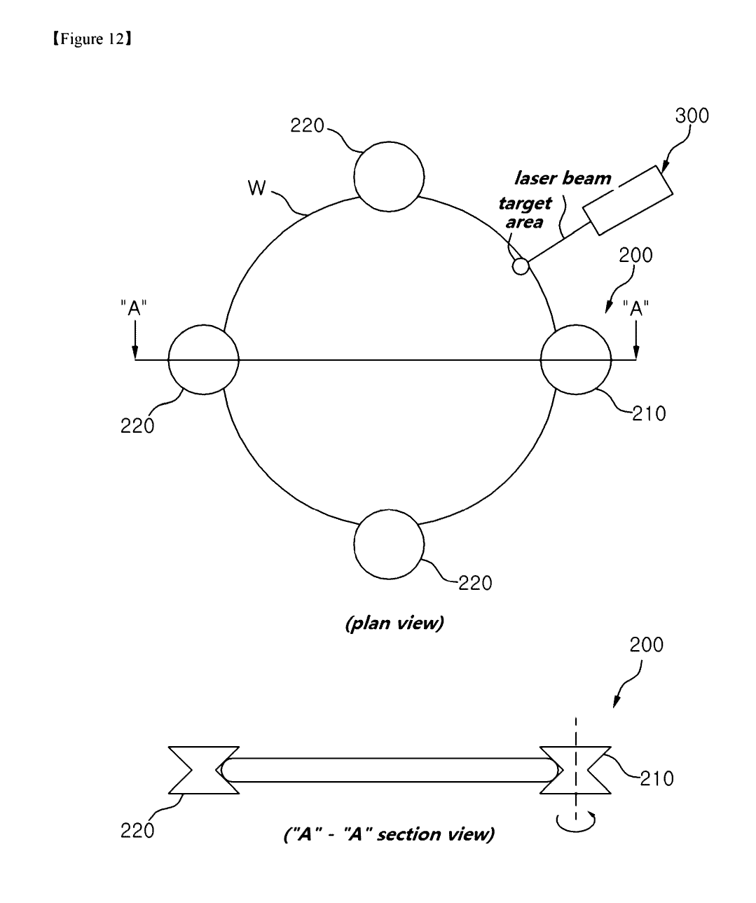

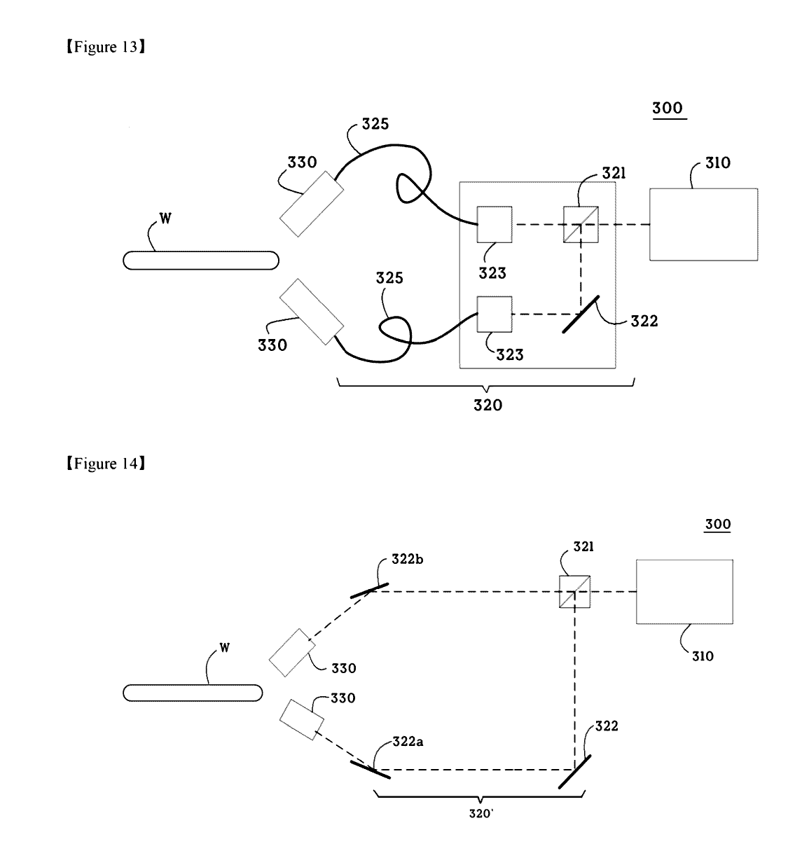

Referring to FIG. 11 and FIG. 12, the wafer edge cleaning apparatus according to a fifth embodiment of the present invention comprises a liquid ejecting unit 100 for ejecting liquid to a surface of wafer so that the liquid film can be formed on the surface of the wafer (W); a wafer rotating unit 200 for rotating the wafer so that the liquid film can be extended to the edge; a laser beam irradiating unit 300 for irradiating a laser beam passing through the liquid film to the edge of the wafer and applying the laser beam to the foreign substances adhered to the edge in order to remove the foreign substances from the edge. As shown in FIG. 11, the liquid ejecting unit 100 is constructed to form a liquid film on the wafer (W) rotated by the wafer rotating unit 200 hereinafter described in detail. The liquid ejecting unit 100 includes a liquid supplying part 110 and a liquid ejection nozzle 120 for ejecting the liquid come from the liquid supplying part 110 directly onto the wafer (W). It is preferable that the ultra pure water (i.e. the de-ionized water) usually used in the semiconductor manufacturing process is used as the liquid supplied from the liquid supplying part 110 and ejected through the liquid ejection nozzle 120. By reducing the size of the outlet(s) through which the liquid sprayed and spreading the liquid widely at the same time, the collision force between the wafer (W) and the liquid can be reduced, and the damages to the circuit pattern on the wafer surface can be reduced. The wafer rotating unit 200 plays the role of rotating the wafer (W) to move liquid from the front surface of the wafer (W) to the outside of the wafer (W) by the centrifugal force rotation so as to extend the liquid film to the edge of the wafer (W). At this time, the rotation speed of the wafer by the wafer rotating unit 200 is preferable more than 100 rpm so as to ensure the sufficient speed and force of the liquid movement to outside of the wafer (W). The speed and force of the liquid movement increases according to the number of revolutions of the wafer increased. As shown in FIG. 12, it is preferable that the wafer rotating unit 200 may include a plurality of rotors 210, 220, 220 and 220 in contact with the outer portion of the wafer (W) at a plurality of locations. Each of the plurality of rotors 210, 220, 220 and 220 has a depressed portion formed, wherein the outer portion of the wafer (W) can be inserted in the depressed portion and can be in contact with the depressed portion. The plurality of rotors 210, 220, 220 and 220 are constructed to grip the outer portion of the wafer (W) with their depressed portions and to rotate the wafer (W). In this case, the plurality of rotors 210, 220, 220 and 220 comprises an active rotor 210 for rotating the wafer (W) while being in contact with an outer portion of the wafer (W) and a passive rotor 220 being contact with the outer portion of the wafer (w), while being located at the different position from that of the active rotor 210, and rotating together with the active rotor 210 and the wafer (W) according to the rotations of the active rotor 210 and the wafer (W). If the number of the active rotor 210 is one, the plurality of the passive rotors 220 is preferably able to horizontally and reliably support the wafer (W) in cooperation with the active rotor 210. As above, the wafer (W) is supported by the active rotor 210 having its own rotation capability and the passive rotors 220 rotated without its own rotation capability. The actual force for rotating the wafer (W) is obtained from the rotating force of the active rotor 210. As shown in FIG. 12, it is preferable that the total number the rotors 210 and 220 is at least four for the stability. Since the wafer (W) is exposed between the neighboring rotors, a laser beam irradiating unit 300 can perform the cleaning for the wafer (W) by irradiating the laser beam to the edge of the wafer (W) between the rotors. The liquid ejecting unit 100 ejects liquid onto the central region of wafer (W) through the liquid ejection nozzle 120. The liquid film is extended to the edge of the wafer (W), Since the wafer (W) is rotated by the rotating unit 300. So the laser beam can be irradiated to the edge of the wafer (W) through the liquid film. At this time, the laser beam irradiating unit 300 has the linear movement and the rotational movement by a suitable driving device in order to clean the upper surface, side surface and lower surface of the edge totally, i.e. to perform the overall cleaning for the edge of the wafer (W). Referring to FIG. 11 again, the laser beam irradiating unit 300 includes a laser beam generating part 310, a laser beam transmitting part 320, and a laser beam irradiating part 330. The laser beam generating part 310 generates a laser beam having pulse width of 1 msecond or less effective to remove the foreign substance adhered to the edge of the wafer (W). It is preferable that the energy of each pulse of the laser beam is less than 1 J in order to minimize heat damage to the wafer (W). It is preferable that the wavelength of the laser beam is in the range of 200-2000 nm, of which energy is not easily absorbed in the pure water, which easily pass through the pure water, and of which energy is well transmitted to the foreign substances. That wavelength of the laser beam can passes through the pure liquid film and can remove the foreign substance adhered to the edge of the wafer (W) efficiently. The laser beam transmitting part 320 guides the laser beam generated from the laser beam generating unit 310 to the edge of the wafer (W). Preferably, as the laser beam transmitting part 320, an optical fiber may be used to solve the problem such as the alignment of the laser beam. Alternatively, a reflection mirror can be employed as the laser beam transmitting part for transmitting a pulse-wave laser beam to the edge of the wafer. The optical fiber would be a multi mode optical fiber. The multi mode optical fiber has the ability to deliver a pulse-wave laser beam having a uniform energy distribution to the laser beam irradiating part 330. The laser beam irradiating part 330 is constructed to irradiate the laser beam transmitted from the laser beam transmitting part 320 to the pollutant adhered to the edge of the wafer through the liquid film. As mentioned above, the pulse-wave laser beam generated from the laser beam generating part 310 is led to the upper surface of the edge of the wafer (W) by passing through the laser beam transmitting part 320. The laser beam irradiating part 330 controls the shape and size of the laser beam and irradiate the shape and size controlled laser beam on the edge of the wafer. As shown in FIG. 2, the laser beam irradiating part 330 can irritate the laser beam while changing the irradiation angle of the laser beam in order to effectively remove the contaminants of the edge of the wafer (W). By changing the irradiation angle of the laser beam, it is possible to clean the entire edge region of the wafer with a laser beam. For changing the irradiation angle of the laser beam, the automated robots can be used. The automated robots holds the laser beam irradiation part 330, and change the angle of the laser beam irradiation part 330 performing the laser beam cleaning for the edge of the wafer. Since the contaminations adhered to the edges are mostly concentrated in less than about 3 mm from the periphery of the wafer (W), it is preferable that the apparatus may clean the 3 mm inside upper surface area from the periphery of the wafer, the 3 mm inside lower surface area from the periphery of the wafer, and the side surface of the wafer. The laser beam irradiation part 330 includes a collimation lens 330a for making the laser beam spreading from the end of the laser beam transmission part 320 into parallel laser beam and a irradiation lens 330b for focusing and irradiating the laser beam to the edge of the wafer (W). The diameter (d) of the terminal laser beam finally radiated to the wafer (W) can be adjusted by changing the distance (L) between the terminal of the laser beam irradiating part 330 and the wafer (W). If the terminal position of the laser beam irradiating part 330 is too close to the wafer (W), an irradiation lens 330b located at the terminal position of the laser beam irradiating part 330 may be contaminated due to a liquid spray that may occur during the cleaning. Because of this, a distance of minimum 50 mm should be maintained between the laser beam irradiating part 330 and the wafer (W). Even if the diameter (d) of the laser beam is less than 1 mm, it is possible to secure a sufficient cleaning rate because of the fast rotation of wafer (W). It is preferable that the average energy density of the laser beam for the laser beam cleaning is 10 J/cm² or less. If the average energy density of the laser beam is higher than 10 J/cm², the silicon base material for the wafer (W) would be damaged. The pulse of the laser beam irradiated to the contaminants is preferably not more than 10 pulses at the same location. The laser beam having more than 10 pulses may cause damage to the silicon base material for the wafer because of the accumulated heat. Referring to FIG. 13, the wafer edge cleaning apparatus according to the sixth embodiment of the present invention comprises a laser beam irradiating unit 300 for irradiating the laser beam on the edge of the wafer (W) in the middle of rotating, wherein the laser beam irradiating unit 300 includes a beam division part as a part of the laser beam transmitting part 320 to division the laser beam generated by the laser beam generating unit 310 into two laser beams in order to increase the cleaning rate for the edge of the wafer (W). In addition, the laser beam irradiating unit 300 includes two laser beam irradiating parts 330 and 330 for irradiating two divided laser beams to the edge of the wafer (W). In addition, the beam division part includes a beam splitter 321 for splitting the laser beam in half and half, a reflection mirror 322 for reflecting the split laser beam, and a beam coupler for focusing the split laser beam to an optical fiber 325. The split laser beams such as these are delivered to the two laser beam irradiating units 330 and 330 through the optical fiber 325 of the optical transmitting part 320. The two laser beam irradiating part 330 irradiates the laser beams to the edge of the wafer in their positions facing each other. When the two laser beam irradiating parts 330 arranged as shown in FIG. 13 irradiates the laser beam, the laser beam cleaning for edge of the wafer (W) can be performed through the wafer rotation of only 90 degrees at the same time, through which the cleaning rate for the edge of the wafer (W) can be increased two times. In addition, because, the two split lasers beam are used which are split from the laser beam generated by the laser beam generating unit, it is not required to buy two laser source and reduce the cost greatly.

Referring to FIG. 14, the wafer edge cleaning apparatus according to a seventh embodiment of the present invention includes a laser beam transmitting part 320′, wherein the laser beam transmitting part 320′ transmits the laser beam by using the reflection mirror without any optical fiber, in place of the laser beam transmitting part using the optical fiber.

The beam splitter 321 is arranged at the front end side of the laser beam transmitting part 320′ to divide the laser beam generated by the laser beam generating part 310 into the two split laser beams. And then, a plurality of reflection mirrors 322, 322a and 322b transmits each of the two laser beams to each of the two laser irradiating part 330. As shown in FIG. 14, a group of the reflection mirrors 322 and 322a are involved in the transmission of a split laser beam, and another reflection mirror 322b is involved in the transmission of another split laser beam. The apparatus illustrated in FIG. 14 has a simple structure but requires the precise alignment of the reflection mirrors for laser beam transmission.

The wafer edge cleaning method in accordance with several embodiments of the present invention using a liquid film has advantages that does not damage the surface of the wafer and is able to selectively clean the edge of the wafer quickly without re-contamination of the wafer edge, in comparison with the conventional chemical wet cleaning method, the plasma cleaning method and the conventional laser beam cleaning method.

### INDUSTRIAL APPLICABILITY

The laser beam cleaning methods and apparatuses according to various embodiments of the present invention, can efficiently and quickly remove the foreign substances adhered to the back and/or edge of the wafer by using a laser beam. Thus the laser beam cleaning methods and apparatuses can be used in the following processes:

a. process for manufacturing semiconductor using a wafer.

b. process for forming fine patterns which needs a precise exposure process.

Furthermore, the present invention cannot be applied to only the back surface or edge of the wafer, but also to the back surface or edge of the substrate of another type, particular glass substrate not but wafer. The cleaning for the edge or the surface of the grass may be used to the following processes:

c. process for manufacturing a flat display including LCD or OLED.

d. process for manufacturing touch panel

e. process for removing foreign substances completely on the surface of the grass substrate.

1.-27. (canceled)

28. A wafer back surface cleaning apparatus for removing foreign substance on a back surface of a wafer with a pulse-wave laser beam, comprising:
a rotating unit for rotating the wafer in condition that the outer portion of the back surface of the wafer is exposed; and
a laser beam irradiating unit for irradiating a pulse-wave laser beam onto the outer portion of the back surface of the wafer, wherein the pulse-wave laser beam irradiated location on the wafer changes depending on the rotation of the wafer.

29. The wafer back surface cleaning apparatus according to claim 28, wherein the rotating unit includes a shaft and a fixing chuck provided at the end of the shaft to hold the center portion of the wafer and rotate the wafer by the rotation of the shaft, wherein the area of the fixing chuck is less than the area of the back surface of the wafer so that the outer portion of the back surface can be exposed to the pulse-wave laser beam.

30. The wafer back surface cleaning apparatus according to claim 28, wherein the rotating unit includes at least one support element to support the edge of the wafer and rotate the wafer by its own rotation.

31. The wafer back surface cleaning apparatus according to claim 28, wherein the laser beam irradiating unit includes a laser beam generating part for generating the pulse-wave laser beam, a laser beam transmitting part including an optical fiber for transmitting the pulse-wave laser beam generated by the laser beam generating part, and a laser beam irradiating part, which includes a plurality of lenses, focuses and radiates the pulse-wave laser beam transmitted through the laser beam transmitting part onto the outer portion of the back surface of the wafer.

32. The wafer back surface cleaning apparatus according to claim 31, wherein the laser beam irradiating unit uses a collimation lens and an irradiation lens for changing the diameter of the pulse-wave laser beam irradiated onto the outer portion.

33. The wafer back surface cleaning apparatus according to claim 28, further comprising a liquid ejecting unit for ejecting liquid onto the back surface of the wafer in order to remove the foreign substance separated from the back surface of the wafer by laser beam irradiation.

34. A wafer cleaning system comprising:
a wafer load port on which a wafer carrier is mounted;
a wafer transfer part including a wafer transfer robot for picking out the wafer from the wafer carrier and transferring the wafer; and
a wafer cleaning part for receiving the wafer from the wafer transfer robot and then cleaning the wafer,
wherein the wafer cleaning part includes a laser beam cleaning module for cleaning the back surface of the wafer with a pulse-wave laser beam, a wet cleaning module for wet-cleaning the wafer cleaned by the laser beam cleaning module, a wafer dispensing unit for unloading/loading the wafer from/to the wet cleaning module or the laser beam cleaning module, wherein, the laser beam cleaning module includes a rotating unit for rotating the wafer in condition that the back surface of the wafer is exposed, a laser beam irradiating unit for irradiating a pulse-wave laser beam onto the outer portion of the back surface of the wafer, wherein the laser beam irradiated location on the wafer changes depending on the rotation of the wafer, and a liquid ejecting unit for ejecting liquid onto the back surface of the wafer in order to remove the foreign substance separated from the back surface of the wafer by the pulse-wave laser beam irradiation.

35. A wafer cleaning method comprising:
a laser beam cleaning step for cleaning a back surface of a wafer with a pulse-wave laser beam;
a wet-cleaning step for wet-cleaning the wafer after the laser beam cleaning step; and
a step for rinsing and drying the wafer after the wet-cleaning step,
wherein the laser beam cleaning step comprises a step for rotating the wafer in condition that the outer portion of the back surface is exposed; and a step for irradiating the pulse-wave laser beam onto the outer portion of the back surface of the wafer, wherein the laser beam irradiated location on the wafer changes depending on the rotation of the wafer; and a step for ejecting liquid onto the outer potion of the back surface of the wafer in order to remove the foreign substance separated from the back surface of the wafer by the pulse-wave laser beam irradiation.

36. A wafer back surface cleaning apparatus for removing foreign substance on a back surface of a wafer with a pulse-wave laser beam, comprising:
a laser beam generating part for generating a pulse-wave laser beam having pulse width of 1 millisecond or less;
a laser beam transmitting part for transmitting the pulse-wave laser beam generated by the pulse-wave laser beam generating part;
a laser beam irradiating part for irradiating the pulse-wave laser beam transmitted through the laser beam transmitting part;
a wafer supporting part for supporting the wafer so that the front surface of the wafer faces upwards and the back surface of the wafer faces downwards, while allowing the exposure of the back surface of the wafer to the pulse-wave laser beam generated from the lager generating part.

37. The wafer back surface cleaning apparatus according to claim 36, wherein the laser beam irradiating part includes a collimation lens and an irradiation lens for changing the diameter of the pulse-wave laser beam irradiated onto the back surface of the wafer, the irradiation lens is 50 mm or more apart from the back surface of the wafer.

38. The wafer back surface cleaning apparatus according to claim 36, the wafer supporting part includes at least one fixing clamp for fixing the wafer by holding the edge of the wafer, wherein a stage connected to the fixing clamp can move the wafer in X-Y linear movement and rotational movement.

39. The wafer back surface cleaning apparatus according to claim 36, further comprising a controller for obtaining information about the location of the foreign substance on the back surface of the wafer from an exposure device or a particle inspection system and for controlling a relative motion between the wafer supporting part and the laser beam irradiating part on a basis of the information, so that the pulse-wave laser beam can be irradiated to only the foreign substance locally.

40. The wafer back surface cleaning apparatus according to claim 36, further comprising a dust collecting part movably disposed in the vicinity of the back surface of the wafer, which collects dust generated during the cleaning of the foreign substance by the pulse-wave laser beam.

41. A wafer back surface dry-cleaning method for removing foreign substance on a back surface of a wafer with a laser beam, comprising following steps:
supporting the wafer in condition that the back surface of the wafer is exposed;
generating a pulse-wave laser beam having pulse width of 1 millisecond or less by using laser beam generating part; and
irradiating the pulse-wave laser beam onto the back surface of the wafer by using a laser beam irradiating part.

42. The wafer back surface dry-cleaning method according to claim 41, further comprising following steps:
determining an irradiation location at which the pulse-wave laser beam will be irradiated on the back surface of the wafer; and
moving the laser beam irradiating part on a basis of the irradiation location determined,
wherein, the irradiation location is determined on the basis of the information about the location of the foreign substance on the back surface of the wafer, obtained from an exposure device or a particle inspection system.

43. A wafer edge cleaning apparatus comprising:
a liquid ejecting unit for ejecting liquid onto a surface of a wafer so that a liquid film can be formed on the surface;
a wafer rotating unit for rotating the wafer so that the liquid film can be extended to the edge of the edge;
a laser beam irradiating unit for irradiating a laser beam to the foreign substance adhered to the edge of the wafer through the liquid film.

44. The wafer edge cleaning apparatus according to claim 43, wherein the wafer rotating unit includes a plurality of rotors for holding the periphery of the wafer and rotating the wafer, and wherein the plurality of rotors includes an active rotor, while being in contact with the periphery of the wafer at one location, to rotate the wafer, and a passive rotor rotating together with the active rotor and the wafer, while being in contact with the wafer at another location.

45. The wafer edge cleaning apparatus according to claim 43, wherein the laser beam irradiating unit includes a laser beam generating part for generating a laser beam, a laser beam transmitting part comprising an optical fiber for transmitting the laser beam generated by the laser beam generating part, and a laser beam irradiating part for receiving the laser beam through the laser beam transmitting part and irradiating the laser beam onto the foreign substance adhered to the edge of the wafer through the liquid film, wherein the laser beam irradiating part includes a collimation lens for making the laser beam spreading from the end of the laser beam transmitting part into parallel laser beam, and a irradiation lens for concentrating the laser beam onto the edge of the wafer.

46. The wafer edge cleaning apparatus according to claim 43, wherein the laser beam irradiating unit includes a beam splitter for splitting the laser beam in half and half, and at least one of a reflection mirror for reflecting the split laser beam and a beam coupler for focusing the split laser beam to an optical fiber, in order to irradiate two split laser beams on to the foreign substance adhered to the wafer.

47. A wafer edge cleaning method comprising steps:
forming a liquid film on a surface of a wafer;
rotating the wafer so that the liquid film can be extended to an edge of a wafer; and
irradiating a laser beam onto the edge of the wafer through the liquid film, so as to clean the contaminants adhered to edge of the wafer.
